(19) United States
(12) Patent Application Publication
(10) Pub. No.: US 2023/0369555 A1
(43) Pub. Date: Nov. 16, 2023

(54) ELECTRONIC DEVICE

(71) Applicant: PanelSemi Corporation, New Taipei City (TW)

(72) Inventors: Yi-Hua WU, New Taipei City (TW); Chin-Tang LI, New Taipei City (TW)

(21) Appl. No.: 18/316,706

(22) Filed: May 12, 2023

(30) Foreign Application Priority Data
May 12, 2022 (TW) 111117926
Apr. 21, 2023 (TW) 112115052

(51) Int. Cl. H01L 33/62; H01L 25/075

(52) U.S. Cl. CPC H01L 33/62; H01L 25/0753

(57) ABSTRACT

An electronic device includes a substrate, a trace layer and a plurality of electronic components. The substrate defines a thickness less than or equal to 100 µm. The substrate further defines a plurality of transmittances, and at least one of the transmittances is greater than 20% under the condition of the wavelength of light being between 500 nm and 1300 nm. The trace layer is arranged on the substrate, and the trace layer includes a plurality of connection pads. The electronic components are arranged on the substrate. Each electronic component is provided with at least one electrode, which is arranged on a face of the electronic component facing the substrate. At least one electrode of each electronic component is eutectic bonded to one of the connection pads.

### CROSS REFERENCE TO RELATED APPLICATIONS

This Non-provisional application claims priority under 35 U.S.C. §119(a) on Patent Application No. 111117926 filed in Taiwan, Republic of China on May 12, 2022, and Patent Application No. 112115052 filed in Taiwan, Republic of China on Apr. 21, 2023, the entire contents of which are hereby incorporated by reference.

### BACKGROUND

### Technology Field

The present disclosure relates to an electronic device and, in particular, to an electronic device having improved connection yield.

### Description of Related Art

The flip-chip bonding technology is widely used in the semiconductor packaging process. Generally speaking, there are roughly three flip-chip bonding methods to bond electronic components (e.g. chips) to substrates. The first flip-chip bonding method is to utilize solder bumps. The second flip-chip bonding method is to utilize anisotropic conductive (adhesive) film (ACF). The third flip-chip bonding method is to utilize metal-to metal fastening. Regarding the above three flip-chip bonding methods, the first and second flip-chip bonding methods are most commonly used. In practice, the first flip-chip bonding method is often used in the general chip packaging process, while the second flip-chip bonding method is often used in the manufacturing process of, for example, liquid crystal displays.

In the second flip-chip bonding method, the most common problem is that the electrodes on the chips cannot be 100% in contact with the conductive balls in the anisotropic conductive adhesive, which leads to a decrease in production yield. In order to avoid this problem (decrease in production yield), the area of the chip electrode should not be too small, but in this way, it will limit the further shrinking of chip area.

Therefore, it is desired to provide a bonding method that can improve the bonding yield between electronic components and substrate so as to shrink the area of chip electrodes.

### SUMMARY

One or more exemplary embodiments of this disclosure are to provide an electronic device that can be manufactured with a bonding method sufficiently utilizing the transmittance characteristics of substrate.

An electronic device of one exemplary embodiment includes a substrate, a trace layer and a plurality of electronic components. The substrate defines a thickness less than or equal to 100 µm. The substrate further defines a plurality of transmittances, and at least one of the transmittances is greater than 20% under the condition of a wavelength of light being between 500 nm and 1300 nm. The trace layer is arranged on the substrate, and the trace layer includes a plurality of connection pads. The electronic components are arranged on the substrate. Each of the electronic components includes at least one electrode arranged on a face thereof facing towards the substrate. The at least one electrode of each electronic component is eutectic bonded to one of the connection pads.

In one exemplary embodiment, the substrate is a resilient substrate.

In one exemplary embodiment, the transmittance is greater than 30% under the condition of the wavelength of light being greater than 550 nm.

In one exemplary embodiment, the transmittance is greater than 40% under the condition of the wavelength of light being greater than 550 nm.

In one exemplary embodiment, the transmittance is greater than 55% under the condition of the wavelength of light being greater than 550 nm.

In one exemplary embodiment, the transmittance is less than 100% under the condition of the wavelength of light being less than 1300 nm.

In one exemplary embodiment, the transmittance is less than 95% under the condition of the wavelength of light being less than 1300 nm.

In one exemplary embodiment, a thickness of tin material of less than 10 µm is defined for each connection pad.

In one exemplary embodiment, a thickness of tin material of less than 10 µm is defined for the at least one electrode of each electronic component.

In one exemplary embodiment, a thickness of tin material of less than 10 µm is defined for where between the substrate and between at least one of the electronic components.

In one exemplary embodiment, a face of the substrate arranged with the electronic components is defined as an upper surface, another face of the substrate away from the electronic components is defined as a lower surface, and a gap less than 20 µm is defined between the upper surface of the substrate and the face of one of the electronic components facing the substrate.

In one exemplary embodiment, the electrode and the connection pad are eutectic bonded by laser bonding.

In one exemplary embodiment, a face of the substrate arranged with the electronic components is defined as an upper surface, another face of the substrate away from the electronic components is defined as a lower surface, and the laser bonding is to provide a laser in a direction from the lower surface of the substrate to the upper surface of the substrate.

In one exemplary embodiment, the laser bonding is to provide a laser to irradiate at least one connection pad.

In one exemplary embodiment, the laser bonding is provided to irradiate where the at least one electrode of one of the electronic components and the corresponding connection pad approach to or contact with each other.

In one exemplary embodiment, the electronic components are self-illuminous components.

In one exemplary embodiment, the thickness of the substrate is less than or equal to 50 µm.

In one exemplary embodiment, the thickness of the substrate is less than or equal to 20 µm.

In one exemplary embodiment, one of the connection pads and the electrode of the corresponding electronic component define an area ratio, and the area ratio is greater than or equal to 1 and less than or equal to 6.

### BRIEF DESCRIPTION OF THE DRAWINGS

The disclosure will become more fully understood from the detailed description and accompanying drawings, which are given for illustration only, and thus are not limitative of the present disclosure, and wherein:

FIGS. 1A to 1C and FIGS. 2A to 2B are schematic diagrams showing different aspects of electronic devices according to an embodiment of this disclosure; and

FIG. 3 is a schematic diagram showing the relationship between the transmittance of substrate and the wavelength of light in the electronic device according to the embodiment.

### DETAILED DESCRIPTION OF THE DISCLOSURE

The present disclosure will be apparent from the following detailed description, which proceeds with reference to the accompanying drawings, wherein the same references relate to the same elements. The drawings of the following embodiments only illustrate the relative relationship between elements or units, and do not represent the actual size or proportion of the elements or units.

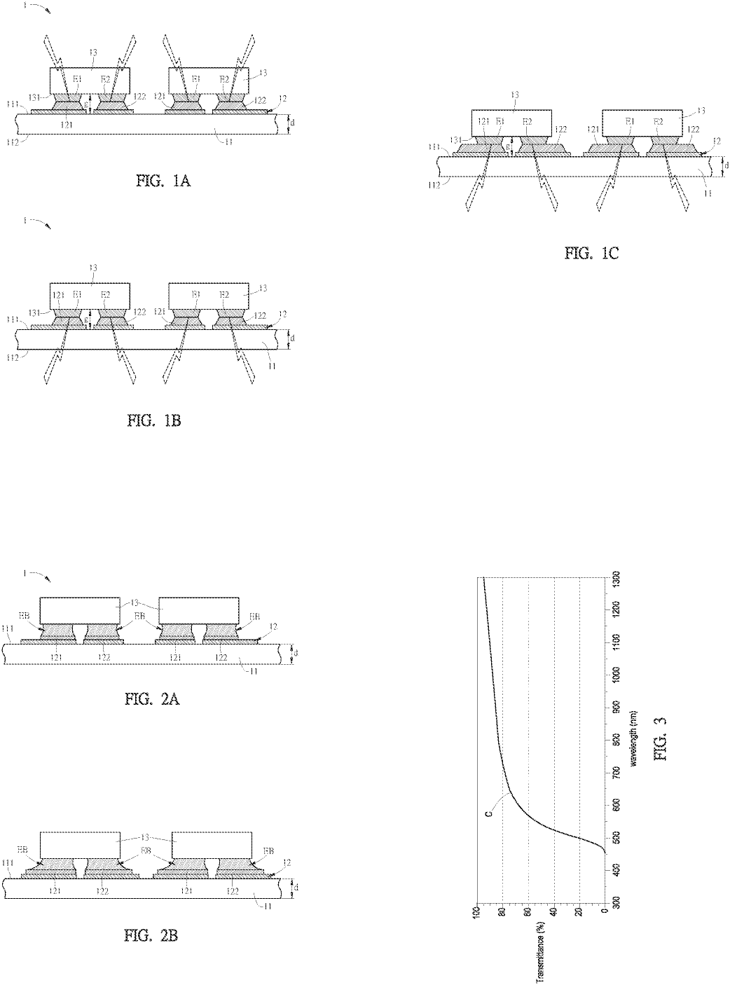

FIGS. 1A to 1C and FIGS. 2A to 2B are schematic diagrams showing different aspects of electronic devices according to an embodiment of this disclosure, and FIG. 3 is a schematic diagram showing the relationship between the transmittance of substrate and the wavelength of light in the electronic device according to the embodiment.

Referring to FIGS. 1A to 1C, 2A to 2B, and 3, the electronic device 1 includes a substrate 11, a trace layer 12, and a plurality of electronic components 13.

The substrate 11 is made of a light-transmitting material, and the substrate 11 can be a resilient substrate. The material of the substrate 11 can be, for example but not limited to, polyimide (PI), polyethylene terephthalate (PET), polycarbonate (PC) or cyclic olefin polymer (COP), or any of other materials, or any combination including any of the aforementioned materials. In this embodiment, the material of the substrate 11 is PI. The substrate 11 defines a thickness d, which is greater than 0 and less than or equal to 100 µm (0 ≤ d ≤ 100 µm). In some embodiments, the substrate can be a light-transmitting glass substrate, and the thickness of the glass substrate is less than or equal to 100 µm. In some embodiments, the glass substrate may have deformation and be formed with slight curvature(s), under the condition of being less than or equal to 100 µm. In this embodiment, the electronic components 13 is arranged on the face 111 of the substrate 11, and the thickness d of the substrate 11 is defined as a thickness measured as being perpendicular to the face 111. The substrate 11 generally has a uniform thickness d, but this disclosure is not limited thereto. In the case of the thickness d of the substrate 11 being uneven, it is defined as the minimum thickness of the substrate 11. In some embodiments, the thickness d of the substrate 11 can be 50 µm, 20 µm, or less.

As shown in FIG. 3, the substrate 11 can further define a plurality of transmittances, and at least one of the transmittances is greater than 20% under the condition of the wavelength of light being between 500 nm and 1300 nm (i.e., transmittance ≥ 20% while the light wavelength is greater than 500 nm). In FIG. 3, the curve C is the transmittance curve measured under the condition of the thickness d of the substrate 11 is 25 µm. In some embodiments, the transmittance of the substrate 11 can be greater than 30% under the condition of the wavelength of light being greater than 550 nm (i.e., transmittance ≥ 30% under the condition of the light wavelength is greater than 550 nm). In some embodiments, the transmittance of the substrate 11 can be greater than 40% under the condition of the wavelength of light being greater than 550 nm, or the transmittance of the substrate 11 can be less than 100% or 95% under the condition of the wavelength of light being less than 1300 nm.

The trace layer 12 is arranged on the substrate 11. In some embodiments, the trace layer 12 is arranged on one face of the substrate 11. In some embodiments, the trace layer 12 can include a conductive layer or/and wires for transmitting electrical signals, so that the substrate 11 can be a circuitry substrate or a driving circuit board for driving the electronic components 13. The trace layer 12 includes a plurality of connection pads 121 and 122. For example, each of FIG. 1A to FIG. 2B shows four connection pads (two connection pads 121 and two connection pads 122). To be noted, the numbers of connection pads 121 and 122 are not limited thereto, and depend on the number of electronic components 13. The material of the trace layer 12 or the connection pads 121 and 122 can include metals (e.g. gold, silver, copper, titanium, tin, or aluminum), any combination of the above metals, an alloy of the above combinations, or any of other conductive materials. The trace layer 12 or the connection pads 121 and 122 can be a single-layer structure or a multi-layer structure. In some embodiments, each of the connection pads 121 and 122 can be defined with a thickness of tin material of less than 10 µm (the thickness of solder (tin) less than or equal to 10 µm). This configuration is beneficial to the subsequent electrical connection process. To be noted, the connection pads 121 and 122 can be a multi-layer structure, and the solder (tin) material can be one layer of solder paste or adhesive in the multi-layer structure and is not independent of each connection pad 121/122. In this case, the thickness of tin material of less than 10 µm of the connection pads 121 and 122 can be formed by electroplating or chemical (electro-less) plating.

The plurality of electronic components 13 are arranged on the substrate 11. First of all, the face of the substrate 11 arranged with the electronic components 13 is defined as an upper surface 111, and the other face of the substrate 11 away from the electronic components 13 is defined as a lower surface 112. In this embodiment, for example, the trace layer 12 and two electronic components 13 are arranged on the upper surface 111 of the substrate 11. In this case, a face 131 of each electronic component 13, facing toward the surface 131 of the substrate 11, is provided with at least one electrode, and at least one electrode of each electronic component 13 is eutectic bonding to one of the connection pads. In this embodiment, the face 131 of one electronic component 13 facing toward the substrate 11 is provided with one electrode E1, and the face 131 of the other electronic component 13 facing toward the substrate 11 is provided with one electrode E2. The electrodes E1 and E2 of the electronic components 13 are eutectic bonding to the corresponding connection pads 121 and 122 respectively (the symbols EB shown in FIG. 2A and FIG. 2B represent “eutectic bonding structures”). In some embodiments, the eutectic bonding may be formed by a laser bonding (laser welding) process. After the electrodes E1 and E2 are respectively connected to the corresponding connection pads 121 and 122, the laser beam, which has high energy and is precisely controllable, can be provided to irradiate any part of/between the electrode E1 (E2) and the corresponding connection pad 121 (122) (e.g. the electrode E1 (E2) or the connection pad 121 (122)), or to irradiate where they approach to or contact with each other. In some embodiments, the laser beam can irradiate the junction region downwardly from the upper surface 111 of the substrate 11 to the lower surface 112 of the substrate 11 (as shown in FIG. 1A), or upwardly from the lower surface 112 of the substrate 11 to the upper surface 111 of the substrate 11 (as shown in FIG. 1B and FIG. 1C). Accordingly, the electrodes E1 and E2 and the corresponding connection pads 121 and 122 can be eutectic bonded respectively to form a flip-chip bonding structure. In some embodiments, the laser beam is provided upwardly to irradiate one of the connection pads (the connection pad 121). In some embodiments, the laser beam is provided downwardly to irradiate the electrodes E1 and E2, or to irradiate the connection junctions of the electrodes E1 and E2 and the corresponding connection pads 121 and 122. In addition, when the electrodes E1 and E2 of the electronic components 13 are directly bonded to the connection pads 121 and 122 respectively, the electrodes E1 and E2 of the electronic components 13 are preferably at least leveled with the faces 131 of the electronic components 13, or protrude beyond the faces 131 of the electronic components 13. This configuration can facilitate the electrodes E1 and E2 to bond with the connection pads 121 and 122 respectively. For facilitating the bonding process, the connection pads 121 and 122 may have a certain height. In some embodiments, similar to the connection pads 121 and 122, the electrodes E1 and E2 of the electronic components 13 can also define a thickness of tin material of less than 10 µm to facilitate the eutectic bonding process. Similarly, the solder (tin) material is one layer of solder paste or adhesive in the multi-layer structure of the electrode E1 (E2) of each electronic component 13 and is not independent of the electrode E1 (E2) of each electronic component 13. It can be understood that the solder (tin) material can be selectively defined in the electrode E1 (E2) of the electronic component 13, or the connection pad 121 (122). In another case, the solder (tin) material can be simultaneously defined in the electrode E1 (E2) of the electronic component 13 and the connection pad 121 (122), and the thicknesses of solder (tin) material on the electrode E1 (E2) of the electronic component 13 and the connection pad 121 (122) can be the same or different. In some embodiments, a gap h defined between the upper surface 111 of the substrate 11 and the face 113 of one of the electronic components 13 facing the substrate 11 is less than 20 µm (as shown in FIGS. 1A to 1C). In some embodiments, a conductive bump (not shown) can be provided between the electrode E1 (E2) and the corresponding connection pad 121 (122), and the material of the conductive bump can include tin, gold, copper, or silver, or an alloy or eutectic containing any of the above materials, or any of other conductive metal materials; in other words, the tin materials are applied therebetween, other than within the electrode E1 (E2) and the corresponding connection pad 121 (122). In other embodiments, the tin material can be a solder paste or adhesive individually arranged or further defined independent from the electrode E1 (E2) of each electronic component 13. To be noted, after the eutectic process, the thickness of tin material of less than 10 µm is defined for where between the substrate 11 and between at least one of the electronic components 13, especially the thickness of tin material of less than 10 µm is defined for where between the area where at least one electrode E1 (E2) of each electronic component 13 and the corresponding connection pad 121 (122). It can be understood that the eutectic bonding structure EB may include at least a part of the electrode E1 (E2) and the corresponding connection pad 121 (122), or the eutectic bonding structure EB may further include at least a part of tin material. In FIG. 2A and FIG. 2B, the proportions, relationships and labels of the eutectic bonding structure EB, the electrode E1 (E2) and the connection pad 121 (122) are for examples only.

In some embodiment, the connection pad can be a single material structure or a composite material structure. In some embodiments, the connection pad can be a single-layer material structure or a multi-layer material structure. The aforementioned single material includes, for example but not limited to, molybdenum (Mo), copper (Cu), titanium (Ti), or the like, and the aforementioned composite material includes, for example but not limited to, titanium nitride (TiNx) or the like. The aforementioned multi-layer material includes, for example but not limited to, a Mo/Cu structure, a TiNx/Cu/Ti structure, or the like. In some embodiments, the substrate 11 includes, for example but not limited to, material layers (including Mo, TiNx and the like), which are provided at where the substrate 11 is connected to the connection pad. The aforementioned materials may help to increase the transmittance, or improve the thermal efficiency of the eutectic process. For example, in the eutectic process performed with a laser beam having a wavelength of 1014 nm, the transmittance of titanium nitride (TiNx) is lower than that of molybdenum (Mo). In other words, under the laser beam with a wavelength of 1014 nm, titanium nitride (TiNx) is easier to absorb the energy of the laser beam than molybdenum (Mo), thereby increasing the thermal efficiency of the laser beam.

In some embodiments, each electronic component 13 can be a photoelectric component, and can further be a self-illuminous component. In some embodiments, each electronic component 13 can be not a photoelectric component. In some embodiments, each electronic component 13 can be a chip or a package, such as a photoelectric chip or a photoelectric package. In some embodiments, each electronic component 13 can be a millimeter-scale or micron-scale photoelectric chip or photoelectric package. In some embodiments, each electronic component 13 can include, for example but not limited to, at least one LED chip, Mini LED chip, Micro LED chip, at least one package, or millimeter-scale, micron-scale or smaller photoelectric chip or photoelectric package with unlimited size. Herein, the millimeter-scale package may include the micron-scale chip.

In some embodiments, the electronic component 13 can be a photoelectric chip or package, or include a photoelectric chip or package, so that the electronic component 13 can be understood as a single pixel, or including multiple pixels. In some embodiments, the electronic component 13 can include a plurality of photoelectric chips or packages, and it can be understood that the electronic component 13 includes multiple pixels. In some embodiments, the electronic component 13 can include a red, blue or green LED chip, Mini LED chip, or Micro LED chip, or a LED, Mini LED, or Micro LED chip or package of any of other colors. When the multiple photoelectric chips or packages included in the electronic component 13 are red, blue and green LED chips, Mini LED chips, or Micro LED chips, the electronic device 1 can be configured as a full-color LED, Mini LED, or micro LED display. In some embodiments, the electronic component 13 can include a chip or package with horizontal electrodes, flip-chip electrodes, or vertical electrodes. The aforementioned packages are not limited to packages with active components or passive packages without active components, wherein the active component can be, for example but not limited to, transistor, silicon IC or non-silicon IC. In some embodiments, the electronic device 1 can further include one or more active components such as, for example but not limited to, TFTs or silicon-semiconductor-based active components corresponding to at least one of the aforementioned electronic components 13. In some embodiments, the electronic component 13 can also be a driving component, which can include at least one transistor, a silicon-semiconductor-based IC or a non-silicon-semiconductor-based IC, for driving other components or packages. The transistor can be a thin-film transistor (TFT).

In some embodiments, one of the connection pads 122 is larger than or equal to the electrode E1 of the corresponding electronic component 13. For example, one of the connection pads 122 and the electrode E1 of the corresponding electronic component 13 define an area ratio, wherein the area ratio can be greater than or equal to 1 (as shown in FIG. 1A, FIG. 1B and FIG. 2A), or the area ratio can be less than or equal to 6 (as shown in FIG. 1C and FIG. 2B). In some embodiments, the area of the electrode E1 of one of the electronic components 13 is less than or equal to 3000 µm², and the area of one of the connection pads 122 is less than or equal to 18000 µm².

As mentioned above, in the electronic device of this disclosure, the substrate is defined with a thickness less than or equal to 100 µm and multiple transmittances therefrom, and one of the transmittances is greater than 20% under the condition of the wavelength of light being greater than 500 nm and less than 1300 nm. The trace layer is arranged on the substrate and includes a plurality of connection pads. The electronic components are arranged on the substrate. At least one electrode provided on one face of each electronic component facing the substrate is eutectic bonded to one of the connection pads. Since one of the transmittances of the substrate is greater than 20% under the condition of the wavelength of light being greater than 500 nm, the light-transmitting characteristics of the electronic device of this disclosure can be fully utilized to allow the laser beam to pass through it, thereby achieving the bonding process of the electronic components and the substrate. In addition, the electrode of each electronic component and the corresponding connection pad of the trace layer are eutectic bonded, so that the area of the electrode of the electronic component and the area of the connection pad of the substrate can be further minimized, which is beneficial to reduce the areas of connection pads and the electrodes of the electronic components. Moreover, this characteristics can also improve the bonding yield between the electronic components and the substrate.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device, comprising:
a substrate defining a thickness less than or equal to 100 µm, wherein the substrate further defines a plurality of transmittances, and at least one of the transmittances is greater than 20% under the condition of a wavelength of light being between 500 nm and 1300 nm;
a trace layer arranged on the substrate, wherein the trace layer comprises a plurality of connection pads; and
a plurality of electronic components arranged on the substrate, wherein each of the electronic components includes at least one electrode arranged on a face thereof facing towards the substrate, and the at least one electrode of each of the electronic components is eutectic bonded to one of the connection pads.

2. The electronic device of claim 1, wherein the substrate is a resilient substrate.

3. The electronic device of claim 1, wherein the transmittance is greater than 30% under the condition of the wavelength of light being greater than 550 nm.

4. The electronic device of claim 1, wherein a thickness of tin material of fewer than 10 microns is defined for where between the substrate and between at least one of the electronic components.

5. The electronic device of claim 1, wherein a face of the substrate arranged with the electronic components is defined as an upper surface, another face of the substrate away from the electronic components is defined as a lower surface, and a gap less than 20 µm is defined between the upper surface of the substrate and the face of one of the electronic components facing the substrate.

6. The electronic device of claim 1, wherein the electrode and the connection pad are eutectic bonded by laser bonding.

7. The electronic device of claim 6, wherein a face of the substrate arranged with the electronic components is defined as an upper surface, another face of the substrate away from the electronic components is defined as a lower surface, and the laser bonding is to provide a laser in a direction from the lower surface of the substrate to the upper surface of the substrate.

8. The electronic device of claim 6, wherein the laser bonding is provided to irradiate where the at least one electrode of one of the electronic components and the corresponding connection pad approach to or contact with each other.

9. The electronic device of claim 1, wherein the electronic components are self-illuminous components.

10. The electronic device of claim 1, wherein the thickness of the substrate is less than or equal to 50 µm.

11. The electronic device of claim 1, wherein one of the connection pads and the electrode of the corresponding electronic component define an area ratio, and the area ratio is greater than or equal to 1 and less than or equal to 6.
